(19) United States
(12) Patent Application Publication
(10) Pub. No.: US 2009/0029502 A1
(43) Pub. Date: Jan. 29, 2009

(54) APPARATUSES AND METHODS OF SUBSTRATE TEMPERATURE CONTROL DURING THIN FILM SOLAR MANUFACTURING

(75) Inventors: Soo Young Choi, Fremont, CA (US); Ankur Kadam, Santa Clara, CA (US); Yong-kee Chae, Pleasanton, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: Applied Materials, Inc.

(21) Appl. No.: 12/178,255

(22) Filed: Jul. 23, 2008

Related U.S. Application Data
(60) Provisional application No. 60/951,690, filed on Jul. 24, 2007.

(51) Int. Cl. H01L 31/18; C23C 16/44; C23C 16/52

(52) U.S. Cl. 438/57; 118/719; 118/696; 257/E31.061

(57) ABSTRACT

Embodiments of the invention generally provide apparatuses and methods of substrate temperature control during thin film solar manufacturing. In one embodiment a method for forming a thin film solar cell over a substrate is provided. The method comprises performing a temperature stabilization process on a substrate to pre-heat the substrate for a substrate stabilization time period in a first chamber, calculating a wait time period for a second chamber, wherein the wait time period is bases on the availability of the second chamber, the availability of a vacuum transfer robot adapted to transfer the substrate from the first chamber to the second chamber, or a combination of both the availability of the second chamber and the availability of the vacuum transfer robot, and adjusting the temperature stabilization time period to compensate for the loss of heat from the substrate during the wait time period.

### CROSS-REFERENCE TO RELATED APPLICATIONS

This application claims benefit of U.S. provisional patent application Ser. No. 60/951,690, filed Jul. 24, 2007, which is herein incorporated by reference.

### BACKGROUND OF THE INVENTION

1. Field of the Invention

Embodiments of the present invention generally relate to apparatuses and methods of substrate temperature control during thin film solar manufacturing.

2. Description of the Related Art

Crystalline silicon solar cells and thin film solar cells are two types of solar cells. Crystalline silicon solar cells typically use either mono-crystalline substrates (i.e., single-crystal substrates of pure silicon) or a multi-crystalline silicon substrates (i.e., poly-crystalline or polysilicon). Additional film layers are deposited onto the silicon substrates to improve light capture, form the electrical circuits, and protect the devices. Thin-film solar cells use thin layers of materials deposited on suitable substrates to form one or more p-i-n junctions.

FIG. 1 is a schematic diagram of certain embodiments of a single p-i-n junction thin film solar cell 100 oriented toward the light or solar radiation 101. Solar cell 100 comprises a substrate 102, such as a glass substrate, polymer substrate, metal substrate, or other suitable substrate. A first transparent conducting oxide (TCO) layer 110 is formed over the substrate 102. A single p-i-n junction 120 comprising a p-doped silicon layer 122, an intrinsic silicon layer 124, and an n-doped silicon layer 126 are formed over the first TCO layer 110. In one embodiment, an amorphous silicon buffer layer (not shown) is formed between the p-doped silicon layer 122 and the intrinsic silicon layer 124. The intrinsic silicon layer 124 typically comprises amorphous silicon. In one embodiment the n-doped silicon layer 126 comprises a dual layer, each layer having a different resistivity. A second TCO layer 140 is formed over the single p-i-n junction 120 and a metal back reflector layer 150 is formed over the second TCO layer 140.

FIG. 2 is a schematic diagram of certain embodiments of a tandem p-i-n junction thin film solar cell 200 oriented toward the light or solar radiation 201. Solar cell 200 comprises a substrate 202, such as a glass substrate, polymer substrate, metal substrate, or other suitable substrate. A first transparent conducting oxide (TCO) layer 210 is formed over the substrate 202. A first p-i-n junction 220 comprising a p-doped silicon layer 222, an intrinsic silicon layer 224, and an n-doped silicon layer 226 are formed over the first TCO layer 210. The intrinsic silicon layer 224 of the first p-i-n junction 220 typically comprises amorphous silicon. In one embodiment, an amorphous silicon buffer layer (not shown) is formed between the p-doped silicon layer 222 and the intrinsic silicon layer 224. A second p-i-n junction 230 comprising a p-doped silicon layer 232, an intrinsic silicon layer 234, and an n-doped silicon layer 236 are formed over the first p-i-n junction 220. The intrinsic silicon layer 234 of the second p-i-n junction 230 typically comprises microcrystalline silicon. A second TCO layer 240 is formed over the second p-i-n junction 230 and a metal back reflector layer 250 is formed over the second TCO layer 240. The tandem p-i-n junction thin film solar cell 200 typically comprises intrinsic silicon layers 224, 234 of different materials so that different portions of the solar radiation spectrum are captured.

Problems with current thin film solar cells include low efficiency and high cost. Therefore, there is a need for improved apparatuses and methods of forming thin film solar cells.

### SUMMARY OF THE INVENTION

Embodiments of the invention generally provide apparatuses and methods of substrate temperature control during thin film solar manufacturing. In one embodiment a method for forming a thin film solar cell over a substrate is provided. The method comprises performing a temperature stabilization process on a substrate to pre-heat the substrate for a substrate stabilization time period in a first chamber, calculating a wait time period for a second chamber, wherein the wait time period is bases on the availability of the second chamber, the availability of a vacuum transfer robot adapted to transfer the substrate from the first chamber to the second chamber, or a combination of both the availability of the second chamber and the availability of the vacuum transfer robot, and adjusting the temperature stabilization time period to compensate for the loss of heat from the substrate during the wait time period.

In another embodiment a method for forming a thin film solar cell over a substrate is provided. The method comprises providing a vacuum system with a transfer chamber, one or more processing chambers coupled with the transfer chamber, a substrate transfer robot disposed in the transfer chamber, and a load-lock chamber coupled with the transfer chamber and having a pre-heat chamber having a plurality of heat elements, pre-heating the substrate to a first temperature in the pre-heat chamber, transferring the substrate with the substrate transfer robot from the pre-heat chamber to a first processing chamber adapted to deposit a p-type silicon layer of a p-i-n junction, and forming a p-type silicon layer on the p-i-n junction o the substrate at a second temperature.

In yet another embodiment a vacuum system for forming a thin film solar cell over a substrate is provided. The system comprises a transfer chamber, one or more processing chambers coupled with the transfer chamber, a substrate transfer robot disposed in the transfer chamber, and a load-lock chamber coupled with the transfer chamber. The load-lock chamber comprising a first evacuable chamber, a second evacuable chamber, and a pre-heat chamber adapted to perform a temperature stabilization process on the substrate for a substrate stabilization time period.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic diagram of certain embodiments of a single p-i-n junction thin film solar cell;

FIG. 2 is a schematic diagram of certain embodiments of a tandem p-i-n junction thin film solar cell;

FIG. 3 is a top schematic view of one embodiment of a process system having a plurality of PECVD process chambers;

FIG. 4 is a top schematic view of another embodiment of a process system having a plurality of PECVD process chambers;

FIG. 5 is a schematic cross-section view of one embodiment of a load-lock chamber; and

FIG. 6 is a schematic cross-section view of one embodiment of a plasma enhanced chemical vapor deposition (PECVD) chamber.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention include improved apparatuses and methods of substrate temperature control during thin film solar manufacturing.

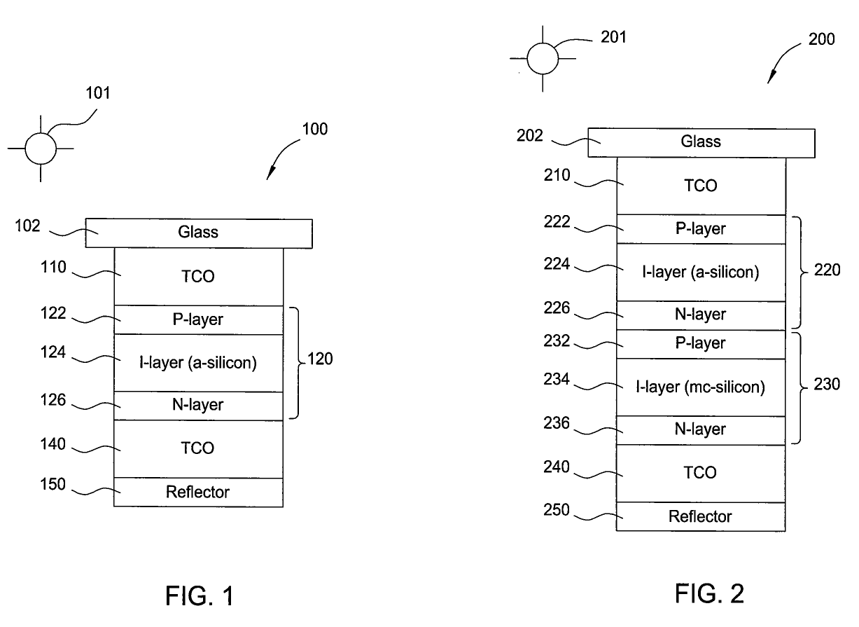

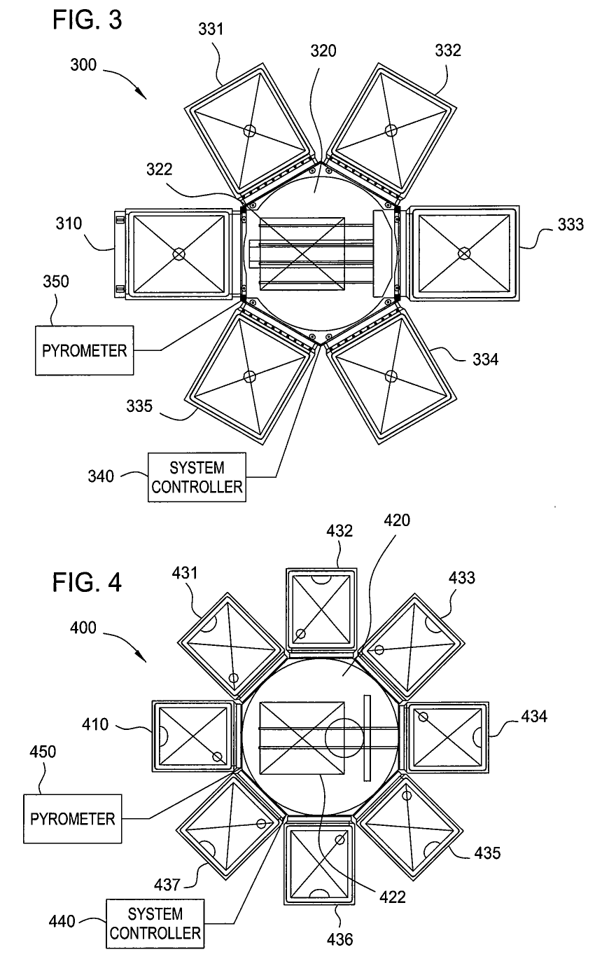

FIG. 3 is a top schematic view of one embodiment of a process system 300 having a plurality of PECVD process chambers 331-335 adapted to deposit silicon films to form a thin film solar cell, such as the solar cells of FIG. 1 and FIG. 2, in a production worthy process. The process system 300 includes a transfer chamber 320 coupled to a load-lock chamber 310 and coupled to the process chambers 331-335. The load-lock chamber 310 allows substrates to be transferred between the ambient environment outside the system and vacuum environment within the transfer chamber 320 and within the process chambers 331-335. The load-lock chamber 310 includes one or more evacuable regions holding one or more substrate. The evacuable regions are pumped down during input of substrates into the system 300 and are vented during output of the substrates from the system 300. The transfer chamber 320 has at least one vacuum robot 322 disposed therein that is adapted to transfer substrates between the load-lock chamber 310 and the process chambers 331-335. A system controller 340 controls the load-lock 310, transfer chamber 320 including the vacuum robot 322, the process chambers 331-335, and a temperature measurement device, such as a pyrometer 350 that is coupled with the system 300. Five process chambers are shown in FIG. 3. However, the system may have any suitable number of process chambers, such as seven process chambers 431-437 in the system 400 as shown in FIG. 4.

FIG. 4 is a top schematic view of another embodiment of a process system 400 having a plurality of PECVD process chambers 431-437. As described with regard to system 300 of FIG. 3, the system 400 of FIG. 4 includes a transfer chamber 420 coupled to a load-lock chamber 410 and coupled to the process chambers 431-437. The load-lock chamber 410 has at least one vacuum robot 422. A system controller 440 controls the load-lock chamber 410, transfer chamber 420 including the vacuum robot 422, the process chambers 431-437, and a temperature measurement device, such as a pyrometer 450 that is coupled with the system 400.

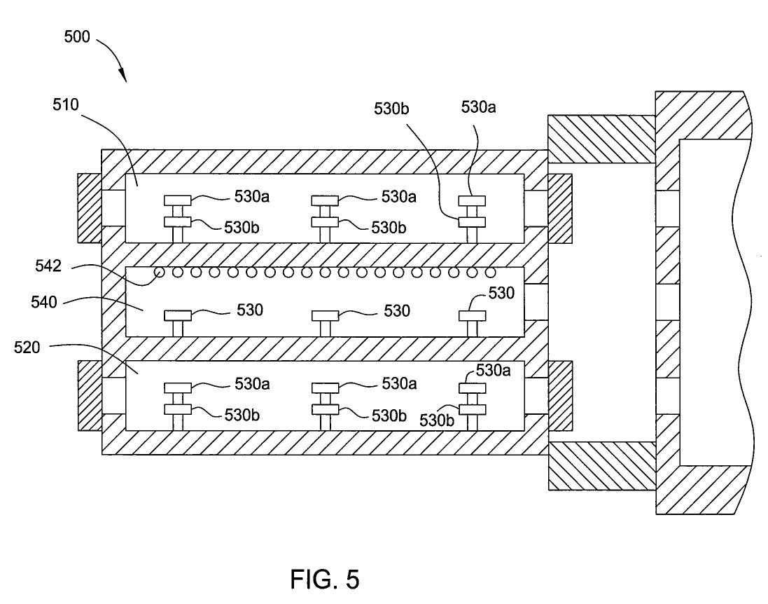

FIG. 5 is a schematic cross-section view of one embodiment of a load-lock chamber 500. The load-lock chamber 500 comprises a first evacuable chamber 510 and a second evacuable chamber 520. As shown, each evacuable chamber 510, 520 has two sets of substrate supports 530a, 530b adapted to hold two substrates. In other embodiments, each evacuable chamber 510, 520 can have any suitable number of sets of substrate supports to hold one or more substrates. The load-lock chamber 500 may further comprise a pre-heat chamber 540 having a plurality of heat elements 542, such as heating lamps, for example, infrared heating lamps, to preheat the substrate. As shown, the pre-heat chamber 540 has one set of substrate supports 530. In other embodiments, the pre-heat chamber can have any suitable number of sets of substrate supports to hold one or more substrates.

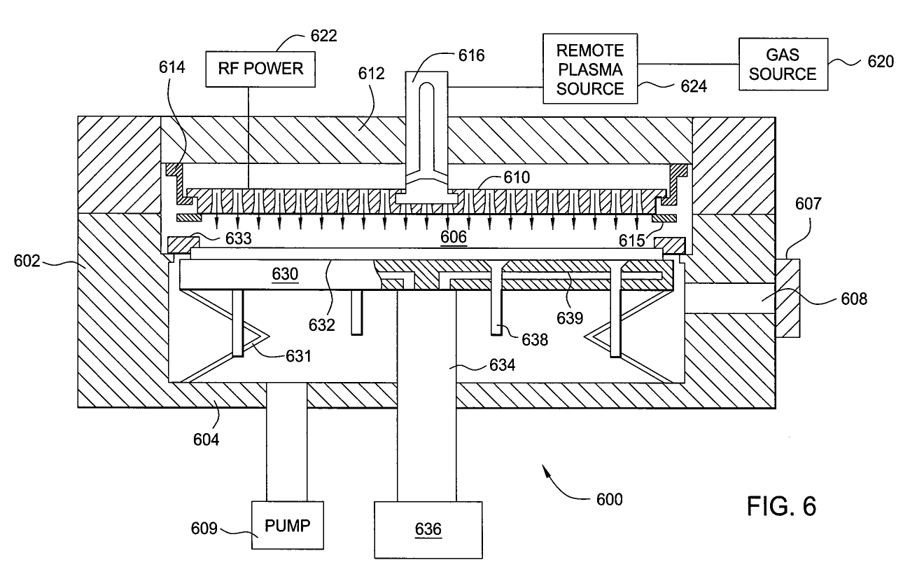

FIG. 6 is a schematic cross-section view of one embodiment of a plasma enhanced chemical vapor deposition (PECVD) chamber 600. One suitable plasma enhanced chemical vapor deposition chamber is available from Applied Materials, Inc., located in Santa Clara, Calif. It is contemplated that other deposition chambers, including those from other manufacturers, may be utilized to practice the present invention.

The chamber 600 generally includes walls 602, a bottom 604, and a showerhead 610, and substrate support 630 which define a process volume 606. The process volume is accessed through a valve 608 such that a substrate may be transferred in and out of the chamber 600. A slit valve door 607 for sealing the valve 608 is provided. The substrate support 630 includes a substrate receiving surface 632 for supporting a substrate and stem 634 coupled to a lift system 636 to raise and lower the substrate support 630. A shadow frame 633 may be optionally placed over periphery of the substrate. Lift pins 638 are moveably disposed through the substrate support 630 to move a substrate to and from the substrate receiving surface 632. The substrate support 630 may also include heating and/or cooling elements 639 to maintain the substrate support 630 at a desired temperature. The substrate support 630 may also include grounding straps 631 to provide RF grounding at the periphery of the substrate support 630.

The showerhead 610 is coupled to a backing plate 612 at its periphery by a suspension 614. The showerhead 610 may also be coupled to the backing plate by one or more center supports 616 to help prevent sag and/or control the straightness/curvature of the showerhead 610. A gas source 620 is coupled to the backing plate 612 to provide gas through the backing plate 612 and through the showerhead 610 to the substrate receiving surface 632. A vacuum pump 609 is coupled to the chamber 600 to control the process volume 606 at a desired pressure. An RF power source 622 is coupled to the backing plate 612 and/or to the showerhead 610 to provide a RF power to the showerhead 610 so that an electric field is created between the showerhead and the substrate support so that a plasma may be generated from the gases between the showerhead 610 and the substrate support 630. Various RF frequencies may be used, such as a frequency between about 0.3 MHz and about 200 MHz. In one embodiment the RF power source is provided at a frequency of 13.56 MHz.

A remote plasma source 624 may also be coupled between the gas source and the backing plate. Between processing substrates, a cleaning gas may be provided to the remote plasma source 624 so that a remote plasma is generated and provided to clean chamber components. The cleaning gas may be further excited by the RF power source 622 provided to the showerhead.

In certain embodiments of the invention, a system, such as system 300 of FIG. 3 or system 400 of FIG. 4, is configured to deposit a single p-i-n junction, such as the single p-i-n junction of FIG. 1 or such as one of the p-i-n junctions 230, 240 of FIG. 2. One of the process chambers (in other words the P-chamber), such as one of the process chambers 331-335 of FIG. 3 or one of the process chambers 431-437 of FIG. 4, is configured to deposit the p-doped silicon layer of the p-i-n junction while the remaining process chambers, such as the remaining process chambers 331-335 of FIG. 3 or the remaining process chambers 431-437 of FIG. 4, are each configured to deposit both the intrinsic type silicon layer and the n-doped silicon layer (in other words the I-N chamber). Thus, a substrate enters the system through the load-lock chamber. In certain embodiments, the vacuum robot transfers the substrate to the pre-heat chamber. The vacuum robot transfers the substrate thereafter into a P-chamber. Then, the vacuum robot transfers the substrate into an I-N chamber. Then, the vacuum robot transfers the substrate back to the load-lock chamber.

In certain instances, the vacuum robot after removing a substrate from a chamber may need to wait for the next chamber to become available, for example, the next chamber may be currently processing a different substrate, process in order to transfer the substrate into the next chamber. For example, the vacuum robot after removing a substrate from a pre-heat chamber may need to wait for the P-chamber to be ready. In another example, the vacuum robot after removing a substrate from a P-chamber may need to wait for an I-N chamber to be ready. While waiting, the substrate experiences a loss in heat. In certain embodiments, the system controller, such as system control 340 of FIG. 3 or system controller 440 of FIG. 4, determines a wait time for the next open chamber. Depending on the wait time on the vacuum robot, the system controller increases the substrate temperature stabilization step that is performed in the next open chamber in order to compensate for the heat loss of the substrate during the wait time.

For example, the vacuum robot removes a substrate from the P-chamber. If the wait time for the I-N chamber on the vacuum robot is between 60 and 70 seconds, then the substrate temperature stabilization step is increased by an additional substrate temperature stabilization time of between 30 seconds and 45 seconds during processing of the substrate that waited on the vacuum robot.

The performance of the solar cell is very sensitive to the temperature of the film growth during the intrinsic layer. Not wishing to be bound by theory it is believed that the p-doped silicon layer and the intrinsic layer interface control is important since damage to the interface may cause diffusion of the p-type dopant from the p-doped silicon layer into the intrinsic silicon layer. Thus, reducing the light collection efficiency from the absorber intrinsic layer due to the increased recombination of electron-hole pairs at the interface of the p-doped silicon layer and the intrinsic layer. In another theory, it is believed that a maintaining the temperature during deposition of the silicon films helps improve quality and conductivity uniformity, and, thus improves efficiency.

Thus, the system controller dynamically adjusts the substrate temperature stabilization time based on the wait time on the vacuum robot. In certain embodiments, adjustment to the substrate temperature stabilization time can be extrapolated from the pre-determined time values for various transfer or vacuum robot waiting time. In other embodiments, adjustment to the substrate temperature stabilization time can be based upon the actual temperature of the substrate. For example, the temperature of the substrate can be measured by a pyrometer located in the transfer chamber or right outside of the PECVD chamber. Then, depending on the temperature of the substrate, the substrate temperature stabilization time is adjusted.

Temperature loss can be measured by using a temperature sensor (pyrometer) that is located in front of deposition chamber such that software can set “extended” stabilization according to the measured temperature from pyrometer.

In certain instances, the substrate must wait for the vacuum robot to be ready to be removed from the P-chamber. Typically, the substrate waits in a non-contact position removed from the substrate support by the lift pins. Thus, the substrate experiences heat loss. To compensate for this loss of heat, if the substrate must wait for the vacuum robot to be ready in order to be removed from the P-chamber while the system controller moves the substrate onto the substrate support in a contact position while the substrate support heating elements heat the substrate until the vacuum robot is available for transfer. During this heating of the substrate, an optional gas flow, such as helium, hydrogen, or another non-reactive gas, may be provided to maintain a uniform substrate temperature. In certain embodiments, the gas flow is provided at high pressure to aid in providing a uniform substrate temperature.

In other embodiments, preheating of the substrate within the preheat chamber is set to a pre-heat temperature slightly above the desired substrate temperature in the P-chamber. The higher pre-heat chamber compensates for loss of heat as the substrate is transferred from the preheat chamber to the P-chamber.

### EXAMPLES

The examples disclosed herein are exemplary in nature and are not meant to limit the scope of the invention unless explicitly set forth in the claims. The process conditions set forth below are exemplary. Other process conditions and ranges may be possible.

### Example 1

Substrates having a surface area of 57,200 cm² and a thickness of 3 mm were processed in a PECVD 60K Thin Film Solar system, to be available from Applied Materials, Inc. of Santa Clara, Calif., to form a single junction P-I-N solar cell. The interior chamber volume of the PECVD 60K Thin Film Solar system is about 2,700 Liters.

Table 1(a) shows the process conditions for deposition of a p-doped amorphous silicon layer in a PECVD chamber with zero or minimal wait time from the pre-heat chamber to the P-chamber. During processing, the pressure was set to between about 1 Torr and 4 Torr; spacing was set between 400 mil and about 800 mil; and the temperature of the substrate support was set to between about 150 degrees Celsius and about 300 degrees Celsius. The p-type dopant was trimethylboron (TMB) provided in 0.5% in a carrier gas such as H₂.

TABLE 1(a)

| | | | TMB (0.5%)/H₂ | | | | |
|---|---|---|---|---|---|---|---|
| | | | carrier | | | | |
| | Silane | Hydrogen | gas | Methane | Argon | RF | Time |
| | (sccm) | (sccm) | (sccm) | (sccm) | (sccm) | (W) | (sec) |
| Temperature | 0 | 0 | 0 | 0 | 75,000 | 0 | 5 |
| Stabilization | | | | | | | |
| Plasma | 0 | 0 | 0 | 0 | 40,000 | 1,500 | 30 |
| Stabilization | | | | | | | |
| P-doped a- | 8,850 | 42,000 | 9,000 | 8,550 | 0 | 2,900 | 22 |
| Silicon | | | | | | | |
| Layer | | | | | | | |

Table 1(b) shows the process conditions for deposition of an intrinsic amorphous silicon layer and n-doped amorphous silicon layer in a PECVD chamber with zero or minimal wait time from the P chamber to the I-N chamber. During processing, the pressure was set to between about 1 Torr and 4 Torr; spacing was set between 400 mil and about 800 mil; and the temperature of the substrate support was set to between about 150 degrees Celsius and about 300 degrees Celsius. The n-type dopant was phosphine provided in a 0.5% molar or volume concentration in a carrier gas such as H₂.

TABLE 1(b)

| | | | PH₃/H₂ | | |
|---|---|---|---|---|---|
| | Silane | Hydrogen | carrier gas | | Time |
| | (sccm) | (sccm) | (sccm) | RF (W) | (sec) |
| Substrate | 0 | 60,000 | 0 | 0 | 20 |
| Temperature | | | | | |
| Stabilization | | | | | |
| Plasma | 0 | 60,000 | 0 | 2,800 | 15 |
| Stabilization | | | | | |
| Intrinsic | 9,000 | 112,500 | 0 | 3,000 | 696 |
| Silicon Layer | | | | | |
| N-doped a- | between | between | between | 3,200 | 49 |
| Silicon Layer | 2,500 | 7,500 and | 1,250 and | | |
| | and | 22,000, | 15,000, for | | |
| | 5,000, | for | example, | | |
| | for | example, | 9,900 | | |
| | example, | 13,500 | | | |
| | 3,000 | | | | |

### Example 2

Substrates having a surface area of 57,200 cm² and a thickness of 3 mm were processed in a PECVD 60K Thin Film Solar system, to be available from Applied Materials, Inc. of Santa Clara, Calif., to form a tandem junction P-I-N solar cell. The interior chamber volume of the PECVD 60K Thin Film Solar system is about 2,700 Liters.

Table 2(a) shows the process conditions for deposition of a p-doped amorphous silicon layer of the first p-i-n junction in a PECVD chamber with zero or minimal wait time from the pre-heat chamber to the P-chamber. During processing, the pressure was set to between about 1 Torr and 4 Torr; spacing was set between 400 mil and about 800 mil; and the temperature of the substrate support was set to between about 150 degrees Celsius and about 300 degrees Celsius. The p-type dopant was trimethylboron (TMB) provided in 0.5% in a carrier gas such as H₂.

TABLE 2(a)

| | | | TMB/H₂ | | | | |
|---|---|---|---|---|---|---|---|
| | Silane | Hydrogen | carrier gas | Methane | Argon | RF | Time |
| | (sccm) | (sccm) | (sccm) | (sccm) | (sccm) | (W) | (sec) |
| Substrate | 0 | 0 | 0 | 0 | 75,000 | 0 | 5 |
| Temperature | | | | | | | |
| Stabilization | | | | | | | |
| Plasma | 0 | 0 | 0 | 0 | 40,000 | 1,500 | 30 |
| Stabilization | | | | | | | |
| P-doped a- | 8,850 | 42,000 | 9,000 | 8,550 | 0 | 2,900 | 22 |
| Silicon Layer | | | | | | | |

Table 2(b) shows the process conditions for deposition of an intrinsic amorphous silicon layer and n-doped microcrystalline silicon layer of the first p-i-n junction in a PECVD chamber with zero or minimal wait time from the P chamber to the I-N chamber. During processing, the pressure was set to between about 1 Torr and 12 Torr; spacing was set between 400 mil and about 800 mil; and the temperature of the substrate support was set to between about 150 degrees Celsius and about 300 degrees Celsius. The n-type dopant was phosphine provided in a 0.5% molar or volume concentration in a carrier gas such as H₂.

TABLE 2(b)

| | | | PH₃/H₂ | | |
|---|---|---|---|---|---|
| | | Hydrogen | carrier gas | RF | Time |
| | Silane (sccm) | (sccm) | (sccm) | (W) | (sec) |
| Substrate | 0 | 60,000 | 0 | 0 | 20 |
| Temperature | | | | | |
| Stabilization | | | | | |
| Plasma | 0 | 60,000 | 0 | 2,800 | 15 |
| Stabilization | | | | | |
| Intrinsic | 9,000 | 112,500 | 0 | 3,000 | 696 |
| Silicon Layer | | | | | |
| N-doped mc- | 600 | 180,000 | 1,300 | 2,100 | 181 |
| Silicon Layer | | | | | |

Table 2(c) shows the process conditions for deposition of a p-doped microcrystalline silicon layer of the second p-i-n junction in a PECVD chamber with zero or minimal wait time from the pre-heat chamber to the P-chamber. During processing, the pressure was set to between about 4 Torr and 12 Torr; spacing was set between 400 mil and about 1,500 mil; and the temperature of the substrate support was set to between about 150 degrees Celsius and about 300 degrees Celsius. The p-type dopant was trimethylboron (TMB) provided in 0.5% in a carrier gas such as H₂.

TABLE 2(c)

| | Silane | Hydrogen | TMB/H₂carrier | RF | Time |
|---|---|---|---|---|---|
| | (sccm) | (sccm) | gas (sccm) | (W) | (sec) |
| Substrate | 0 | 60,000 | 0 | 0 | 5 |
| Temperature | | | | | |
| Stabilization | | | | | |
| Plasma | 0 | 60,000 | 0 | 5,000 | 30 |
| Stabilization | | | | | |
| P-doped mc- | 500 | 325,000 | 500 | 18,000 | 195 |
| Silicon Layer | | | | | |

Table 2(d) shows the process conditions for deposition of an intrinsic microcrystalline silicon layer and n-doped amorphous silicon layer of the second p-i-n junction in a PECVD chamber with zero or minimal wait time from the P chamber to the I-N chamber. During processing, the pressure was set to between about 1 Torr and 12 Torr; spacing was set between 400 mil and about 800 mil; and the temperature of the substrate support was set to between about 150 degrees Celsius and about 300 degrees Celsius. The n-type dopant was phosphine provided in a 0.5% molar or volume concentration in a carrier gas such as H₂.

TABLE 2(d)

| | | | PH3/H₂ | | |
|---|---|---|---|---|---|
| | Silane | Hydrogen | carrier gas | | |
| | (sccm) | (sccm) | (sccm) | RF (W) | Time (sec) |
| Substrate | 0 | 100,000 | 0 | 0 | 20 |
| Temperature | | | | | |
| Stabilization | | | | | |
| Plasma | 0 | 100,000 | 0 | 5,000 | 15 |
| Stabilization | | | | | |
| Intrinsic mc- | 2.042 | 204,200 | 0 | 28,000 | 2,888 |
| Silicon Layer | | | | | |
| N-doped a- | 600 | 180,000 | 1,300 | 2,100 | 181 |
| Silicon Layer | | | | | |

It is understood that embodiments of the invention may also be practiced on in-line systems and hybrid in-line/cluster systems. For example, embodiments of the invention have been described in reference to a first system configured to form a first p-i-n junction and a second p-i-n junction. It is understood that in other embodiments of the invention, the first p-i-n junction and a second p-i-n junction may be formed in a single system. For example, embodiments of the invention have been described in reference to a process chamber adapted to deposit both an intrinsic type layer and an n-type layer. It is understood that in other embodiments of the invention, separate chambers may be adapted to deposit the intrinsic type layer and the n-type layer. It is understood that in other embodiments of the invention, a process chamber may be adapted to deposit both a p-type layer and an intrinsic type layer.

### Example 3

Table 3 is one example of the additional substrate temperature stabilization time provided to the substrate temperature stabilization time as set forth in Examples 2 and 3. The adjustments may be based upon the vacuum robot wait time or on the measured substrate temperature.

TABLE 3

| | | Additional |
|---|---|---|
| Vaccum | Substrate | Heat |
| Robot Wait | Temperature | Stabilization |
| Time (sec) | (° C.) | time (sec) |
| 0 | 200 | 0 |
| 28 | 190 | 23 |
| 30 | 189 | 24 |
| 60 | 182 | 35 |
| 70 | 180 | 38 |
| 115 | 170 | 51 |
| 120 | 169 | 52 |
| 173 | 160 | 63 |
| 180 | 157 | 65 |
| 229 | 150 | 74 |
| 240 | 147 | 76 |
| 290 | 140 | 84 |
| 300 | 137 | 86 |
| 357 | 130 | 95 |
| 600 | 115 | 126 |

Improved apparatuses and methods of substrate temperature control during thin film solar manufacturing with improvement in the variation of solar cell performance in terms of both within-substrate uniformity and run-to-run uniformity have been provided. Without being bound by theory, the inventors have found that the performance of PIN type silicon thin film solar cells is very sensitive to temperature film growth for several reasons. First, window layer P-type semiconductor film quality is very sensitive to temperature due to the conductivity variation caused by temperature. Second, temperature control at the P-type layer and I-type layer interface is important to avoid blue light absorption and if the interface is damaged by diffusion of a dopant from the P-type layer, light collection efficiency from the absorber intrinsic layer will be significantly affected due to enhanced recombination of electron-hole pairs at the P-I interface. Third, if the I-type layer deposition temperature is greater than the threshold temperature for dopant diffusion, increased dopant diffusion to the P-I interface significantly affects solar cell performance. Therefore, there is a need for the apparatuses and methods provided herein which provide accurate temperature control during film deposition processes and substrate transfer during processing.

While the foregoing is directed to embodiments of the present invention, other and further embodiments of the invention may be devised without departing from the basic scope thereof, and the scope thereof is determined by the claims that follow. For example, the process chamber has been shown in a horizontal position. It is understood that in other embodiments of the invention the process chamber may be in any non-horizontal position, such as vertical. For example, embodiments of the invention have been described in reference to the multi-process chamber cluster tool. It is understood that embodiments of the invention may also be practiced in on in-line systems and hybrid in-line/cluster systems. For example, embodiments of the invention have been described in reference to a first system configured to form a first p-i-n junction and a second p-i-n junction. It is understood that in other embodiments of the invention, the first p-i-n junction and a second p-i-n junction may be formed in a single system. For example, embodiments of the invention have been described in reference to a process chamber adapted to deposit both an intrinsic type layer and an n-type layer. It is understood that in other embodiments of the invention, separate chambers may be adapted to deposit the intrinsic type layer and the n-type layer. It is understood that in other embodiments of the invention, a process chamber may be adapted to deposit both a p-type layer and an intrinsic type layer.

1. A method for forming a thin film solar cell over a substrate, comprising:
performing a temperature stabilization process on a substrate to pre-heat the substrate for a substrate stabilization time period in a first chamber;
calculating a wait time period for a second chamber, wherein the wait time period is based on the availability of the second chamber, the availability of a vacuum transfer robot adapted to transfer the substrate from the first chamber to the second chamber, or a combination of both the availability of the second chamber and the availability of the vacuum transfer robot; and
adjusting the temperature stabilization time period to compensate for the loss of heat from the substrate during the wait time period.

2. The method of claim 1, further comprising transferring the substrate to the second chamber after completion of the adjusted temperature stabilization time period.

3. The method of claim 1, wherein performing a temperature stabilization process comprises heating the substrate to a temperature greater than a temperature for processing the substrate.

4. The method of claim 1, wherein adjusting the temperature stabilization time period to compensate for loss of heat comprises increasing the temperature stabilization time period.

5. The method of claim 1, wherein the temperature stabilization time period is based on the actual temperature of the substrate.

6. The method of claim 1, wherein the first chamber is a load-lock chamber comprising a pre-heat chamber having a plurality of heat elements.

7. The method of claim 6, wherein the second chamber is a processing chamber adapted to deposit a p-type silicon layer of a p-i-n junction.

8. The method of claim 1, further comprising:
forming a p-type silicon layer of a p-i-n junction on the substrate in the first chamber after performing the temperature stabilization step; and
forming both an intrinsic type silicon layer and an n-doped silicon layer of the p-i-n junction in the second chamber after completion of the adjusted temperature stabilization time period.

9. The method of claim 1, further comprising:
moving the substrate from a non-contact position wherein the substrate is supported by lift pins to a contact position wherein the substrate is supported by a substrate support; and
heating the substrate with the substrate support until the adjusted temperature stabilization period is complete.

10. The method of claim 9, further comprising:
flowing a non-reactive gas such as helium or hydrogen to maintain a uniform substrate temperature while heating the substrate with the substrate support.

11. A method for forming a thin film solar cell over a substrate, comprising:
providing a vacuum system with a transfer chamber, one or more processing chambers coupled with the transfer chamber, a substrate transfer robot disposed in the transfer chamber, and a load-lock chamber coupled with the transfer chamber, wherein the loadlock chamber comprises a pre-heat chamber having a plurality of heat elements;
pre-heating the substrate to a first temperature in the pre-heat chamber;
transferring the substrate with the substrate transfer robot from the pre-heat chamber to a first processing chamber adapted to deposit a p-type silicon layer of a p-i-n junction; and
forming a p-type silicon layer of the p-i-n junction on the substrate at a second temperature.

12. The method of claim 11, further comprising:
transferring the substrate with the substrate transfer robot from the first processing chamber to a second processing chamber adapted for forming an i-type silicon layer and an n-type silicon layer on the substrate; and
forming an i-type silicon layer and an n-doped type silicon layer on the substrate.

13. The method of claim 11, wherein the first temperature is greater than the second temperature.

14. The method of claim 11, wherein pre-heating the substrate to a first temperature in the pre-heat chamber comprises performing a temperature stabilization process on the substrate for a substrate stabilization time period.

15. The method of claim 14, further comprising:
calculating a wait time period for the first processing chamber, wherein the wait time period is based on the availability of the first processing chamber, the availability of the substrate transfer robot, or a combination of both the availability of the first processing chamber and the availability of the substrate transfer robot; and
adjusting the temperature stabilization time period to compensate for the loss of heat from the substrate during the wait time period.

16. The method of claim 13, wherein the plurality of heat elements is selected from the group comprising an infrared heater, a resistive heating element positioned in a susceptor for supporting the substrate, and combinations thereof.

17. The method of claim 15, further comprising:
moving the substrate from a non-contact position wherein the substrate is supported by lift pins to a contact position wherein the substrate is supported by a substrate support; and
heating the substrate with the substrate support until the adjusted temperature stabilization period is complete.

18. The method of claim 11, wherein the first temperature is greater than a temperature required for p-type growth.

19. A vacuum system for forming a thin film solar cell over a substrate, comprising:
a transfer chamber;
one or more processing chambers coupled with the transfer chamber;
a substrate transfer robot disposed in the transfer chamber; and
a load-lock chamber coupled with the transfer chamber, wherein the load-lock chamber comprises:
a first evacuable chamber;
a second evacuable chamber; and
a pre-heat chamber adapted to perform a temperature stabilization process on the substrate for a substrate stabilization time period.

20. The vacuum system of claim 19, further comprising a system controller adapted to cause the system to perform the following:
performing a temperature stabilization process on a substrate to pre-heat the substrate for a substrate stabilization time period in a first chamber;
calculating a wait time period for a second chamber, wherein the wait time is based on the availability of the second chamber, the availability of the substrate transfer robot, or a combination of both the availability of the second chamber and the availability of the substrate transfer robot; and
adjusting the temperature stabilization time period to compensate for the loss of heat from the substrate during the wait time period.
